(19) United States
(12) Patent Application Publication
(10) Pub. No.: US 2007/0199184 A1
(43) Pub. Date: Aug. 30, 2007

(54) Clasping structure

(75) Inventor: Ted Ju, Keelung (TW)

Correspondence Address: TROXELL LAW OFFICE PLLC;ONE SKYLINE PLACE, SUITE 1404, 5205 LEESBURG PIKE, FALLS CHURSH, VA, 22041, US

(73) Assignee: Lotes Co., Ltd.

(21) Appl. No.: 11/363,035

(22) Filed: Feb. 28, 2006

(51) Int. Cl. A44B 21/00; H05K 7/20

(52) U.S. Cl. 24/459

(57) ABSTRACT

A clasping structure is disclosed, including a clasping part provided with a clasping portion, which clasps an object to be clasped at a clasping point, wherein the clasping portion may swing about an axial line located in the inner side of the clasping point when in the clasping direction. In the present utility model of a novel clasping structure, a clasping portion may swing about an axial line located in the inner side of the clasping point when in the clasping direction, and the clasping portion still has a tendency of moving inward when the clasping point of the clasping part clasps an object to be clasped thereunder such that the clasping structure can effectively clasp the object to be clasped under the clasping portion.

### FIELD OF THE INVENTION

The present invention relates to a clasping structure, and in particular to a clasping structure can effectively clasp an object to be clasped.

### BACKGROUND OF THE INVENTION

Adapter is a bridge for the communication between motherboard and interface devices in a computer. With incessant pursuit of reducing volume in hand-held device, adapter is also developed with an ever decreasing volume.

Mini PCI, for example, the most widely used specification of adapter in a notebook computer, is a horizontal design such that the mini PCI adapter can be installed parallel to the base plate of a computer and, in turn, the height taken can be greatly reduced.

Apart from enhancing the retaining force of the adapter itself, motherboard is usually provided with an auxiliary clasping structure to prevent the adapter from loosing up with connector when bumping or swinging occurs to the adapter. The commonly seen clasping structure, for example the clasping structure disclosed in PRC Patent No. 200320114043.x, is complex coupled with a high production cost. Also, the clasping structure is easily deformed after repeated uses such that adapters are inclined to loose up and then disengage.

It is therefore necessary to design a new clasping structure to overcome the shortcomings described above.

### SUMMARY OF THE INVENTION

An object of the present invention is to provide a clasping structure for effectively clasping objects to be clasped.

In order to accomplish the objects described above, a clasping structure according to the present invention comprises: a clasping part provided with a main body, whose one side extending downward is provided with a holding portion, another side extending upward is provided with a fixing portion, and a still another side of the main body bends and then extends to form an elastic arm. Over the elastic arm, a clasping portion is provided close to the sidewise bent of the main body. On the inner bottom of the clasping portion is provided with a clasping point, and an axial line is provided at the center of the elastic arm; and a base provided with a groove and provided with a first locating bar on its top and with a second locating bar on its bottom corresponding to the first locating bar such that the clasping portion can be accommodated in the groove. Consequently, the clasping portion can swing about the axial line after the clasping structure is being assembled.

In order to accomplish the objects described above, the clasping structure according to the present invention comprises: a clasping part provided with a clasping portion, whose inner bottom is provided with a clasping point and also provided with a pivoting portion corresponding to the clasping portion; a coordinating part having a main body and an elastic arm which is formed by extending one side of the main body upward and then backward with a certain portion springing upward; and a base provided with a groove and disposed with a first locating bar on its top and with a second locating bar on its bottom corresponding to the first locating bar such that the clasping portion can be accommodated in the groove. Consequently, when the clasping part and the coordinating part are assembled into the base, the end of the pivoting portion and its corresponding wall in the coordinating part can limit the swinging angle of the clasp.

Compared with conventional prior arts, the clasping portion of the present utility model of novel clasping structure can swing about an axial line located in the inner side of the clasping point when in the clasping direction, and the clasping portion still has a tendency of moving inward when the clasping point of the clasping part clasps an object to be clasped thereunder such that the clasping structure can effectively clasp the object to be clasped under the clasping portion.

### BRIE DESCRIPTION OF THE DRAWINGS

The present invention can be more fully understood by reference to the following description and accompanying drawings, in which:

FIG. 1 is a plane view schematically illustrating a preferred embodiment of a clasping structure according to the present invention;

FIG. 1 is a perspective assembly view schematically illustrating a preferred embodiment according to the present invention;

FIG. 2 is an exploded perspective view schematically illustrating a preferred embodiment according to the present invention;

FIG. 3 is a cross-sectional view schematically illustrating the clasping part of the clasping structure according to the present invention;

FIG. 4 is an assembly view of the clasping structure according to the present invention, an adapter, an electrical connector, and an electrical board;

FIG. 5 is a schematic illustration of another preferred embodiment of a clasping part according to the present invention;

FIG. 6 is a schematic illustration of another preferred embodiment of a coordinating part according to the present invention;

FIG. 7 is a view schematically illustrating the assembly of the clasping part in

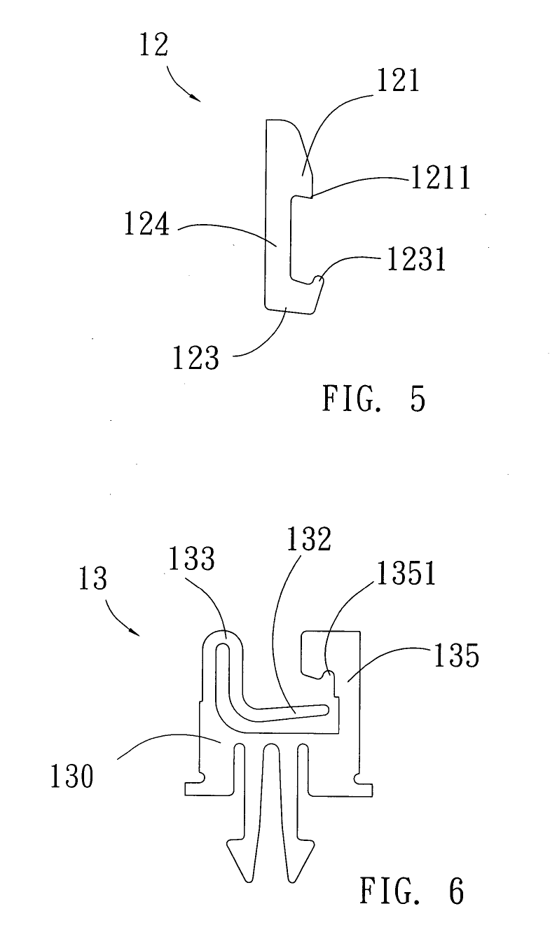

FIG. 5, the coordinating part in FIG. 6, and the base; and

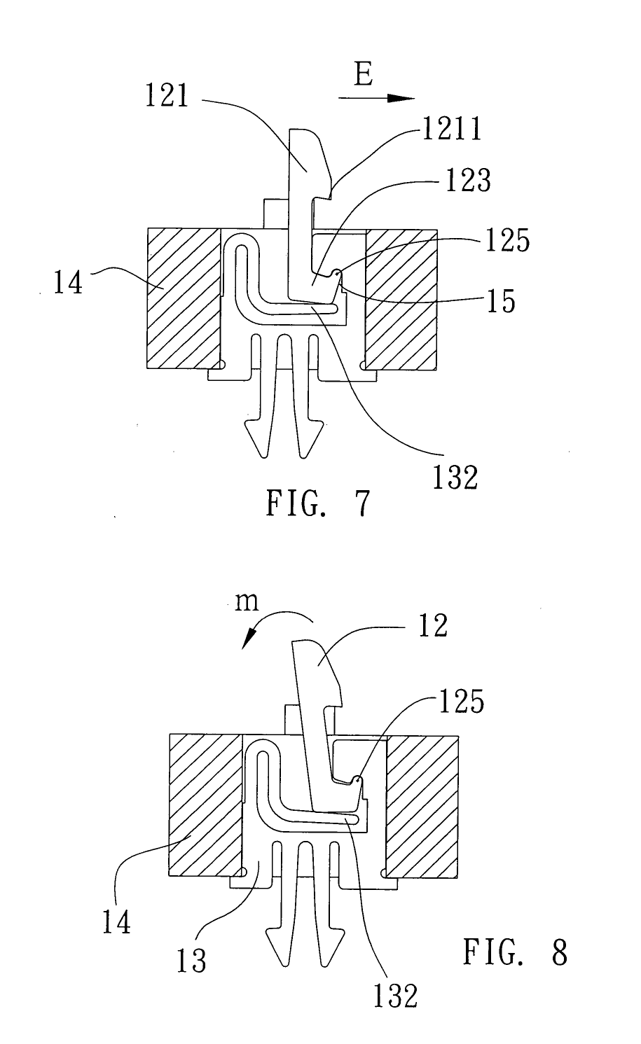

FIG. 8 is a view schematically illustrating the clasping structure shown in FIG. 7 swinging a certain degrees when subjected to a force.

### DETAILED DESCRIPTION OF THE INVENTION

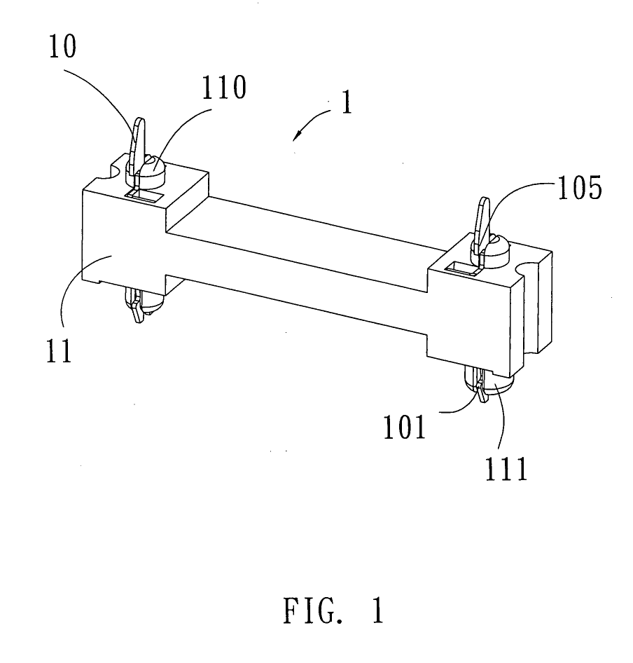

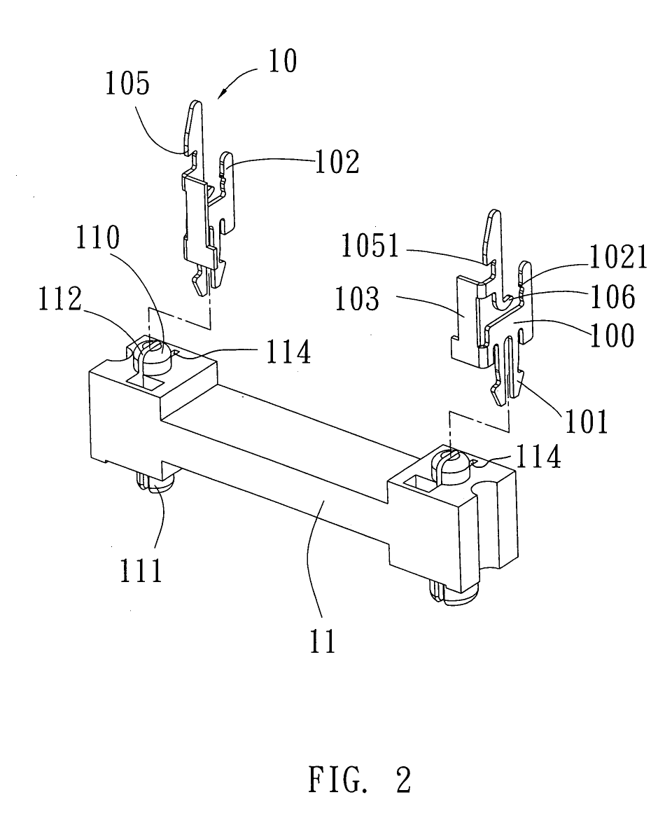

Referring to FIG. 1 to FIG. 4, a clasping structure 1 according to present invention can be secured in an circuit board 5 to clasp an adapter 6 (or connect with other devices such as a circuit board), which is used together with a card edge connector 7 installed on the circuit board 5. The first terminal 61 of the adapter 6 is connected with the card edge connector 7. The clasping structure 1 is secured on the adapter 6, extends toward the first terminal 61 of the adapter 6, and is clasped with the second terminal 62. Also, the clasping structure 1 comprises a clasping part 10 and a base 11, wherein the base 11 is further provided with a groove 112 such that the clasping part 10 can be accommodated therein.

The clasping part 10 is made by stamping and bending a metal sheet, comprising a main body 100 and a holding portion 101 of a fish-spear shape extending downward from the main body 100, wherein the holding portion 101 may be secured in a hole 51 of the circuit board 5 such that the clasping structure 1 may be secured on the circuit board 5.

One side of the main body 100 extends upward and is provided with a fixed portion 102, on which a protruding tip 1021 is provided. The base 11 is provided with a fixing hole 114, in which the fixing portion 102 can be accommodated. In the mean time, another side of the main body 100 bends and then extends to form an elastic arm 103. Over the elastic arm 103, a clasping portion 105 is provided close to the sidewise bent of the main body 100, such that the elastic arm 103 is disposed between the clasping portion 105 and the main body 100. Furthermore, on the inner bottom of the clasping portion 105 is provided with a clasping point 1051.

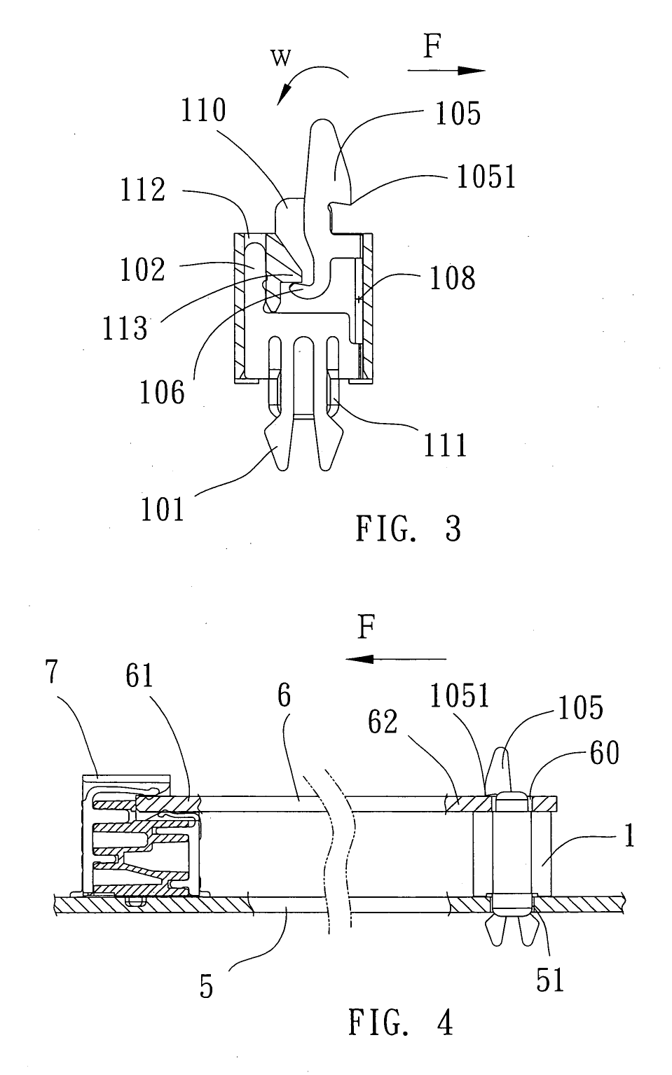

The clasping portion 105 and the main body 100 are located roughly at the same plane. The bottom of the clasping portion 105 extends opposite to the clasping portion 105 and away from the elastic arm 103 to form a limiting portion 106. Also, on the limiting portion 106 along the direction opposite to the clasping direction (the clasping direction F is shown in FIG. 3) is provided with a stop portion 113 corresponding to the groove 112 of the base 11 of the clasping structure 1. When the clasping portion 105 swings, the stop portion 113 is disposed against the limiting portion 106 to prevent the clasping portion 105 from over-swinging.

An axial line 108 is provided near the center of the elastic arm 103 (only a point is shown in the figures because the axial line 108 is perpendicular to the paper) and the axial line 108 is located in the inner side of the clasping point 1051 when in the clasping direction.

A first locating bar 110 is further provided on the upper surface of the base 11 and a second locating bar 111 is provided on the lower surface of the base 11 corresponding to the first locating bar 110. The groove 112 penetrates through the upper and lower surface of the base 11 and the locating bars 110 and 111. The clasping portion 105 of the clasping part 10 is accommodated in the groove 112 and part of the clasping portion 105 protrudes out of the first locating bar 110. The holding portion 101 also partially protrudes out of the second locating bar 111.

When the adapter 6 is being mounted, the first terminal 61 of the adapter 6 is inserted into the card edge connector 7 and then the hole 60 in the adapter 6 is positioned to align with the two first locating bars 110 of the base 11. The adapter 6 is then pressed down into the second terminal 62 of the adapter 6. Consequently, the clasping portion 105 will be forced to move backward (i.e. to swing about the axial line 108 and along the w direction, as shown in FIG. 3). When the hole 60 of the adapter 6 passes through the clasping portion 105, the clasping portion 105 swings about the axial line 108 and along the opposite of w direction. Consequently, the clasping point 1051 is clamped to the upper surface of the adapter 6 and because the axial line 108 is located in the inner side of the clasping point 1051 when in the clasping direction, the clasping portion 105 still has a tendency of moving inward when the clasping point 1051 of the clasping portion 105 clasps the adapter 6 thereunder such that the clasping structure 1 according to the present invention can effectively clasp the adapter 6 under the clasping portion 105. On the other hand, the adapter 6 can be ejected out by pushing the clasping portion 105 along the w direction.

Referring to FIGS. 5 to 8, another embodiment of a clasping structure according to the present invention is shown. Compared with the embodiment described above, the present embodiment of a clasping structure 1 according to the present invention further comprises a coordinating part 13, in addition to a clasping part 12. The clasping part 12 further comprises a clasping portion 121, of which inner bottom is provided with a clasping point 1211. On the clasping part 12 is provided with a pivoting portion 123 opposite to the clasping portion 121. On the end of the pivoting portion 123 protrudes upward to form a protruding tip 1231. A swinging axial line 125 is located in the center of the protruding point 1231, and the axial line 125 is located in the inner side of the clasping point 1231 when in the clasping direction (the clasping direction is shown in FIG. 7 as E).

The clasping portion 121 and the pivoting portion 123 with a connecting portion 124 between them are integrally formed. The coordinating part 13 further comprises a main body 130 and an elastic arm 132 which is formed by extending one side of the main body 130 upward and then backward with a certain portion springing upward. A connecting portion 133 is provided between the elastic arm 132 and the main body 130. The connecting portion 133 is formed by extending the main body 130 upward and backward, and thus the resilience of the elastic arm 132 can be enhanced, wherein the elastic arm 132 presses against the pivoting portion 123 of the clasping part 12.

One side of the main body 130 extends upward to form a fixing portion 135, on which an indent 1351 is provided. The indent 1351 may accommodate the protruding point 1231 of the clasping part 12 and swing relative to each other about the axial line 125. When the clasping part 12 and the coordinating part 13 are installed in the base 14 (as shown in FIGS. 7 and 8), the end of the pivoting portion 123 and its corresponding wall in the coordinating part 13 form an angle of 15°, which may limit the over-swinging angle of the clasping part 12. When the clasping part 12 swings along the direction of m, the existence of the 15° angle may limit the swinging of the clasping part 12. Consequently, the present embodiment can also achieve the goal described in the previous embodiment.

The clasping portion of the clasping structure according to the present invention may swing about an axial line located in the inner side of the clasping point when in the clasping direction, and the clasping portion still has a tendency of moving inward when the clasping point of the clasping part clasps an object to be clasped thereunder such that the clasping structure can effectively clasp the object to be clasped under the clasping portion. Consequently, the clasping structure can overcome the shortcomings of the conventional prior arts of clasping structure.

While the invention has been described with reference to the a preferred embodiment thereof, it is to be understood that modifications or variations may be easily made without departing from the spirit of this invention, which is defined by the appended claims.

What is claimed is:

1. A clasping structure comprising:
a clasping part provided with a main body, whose one side extending downward is provided with a holding portion, another side extending upward is provided with a fixing portion, and a still another side of the main body bends and then extends to form an elastic arm, wherein over the elastic arm, a clasping portion is provided close to the sidewise bent of the main body, on the inner bottom of the clasping portion is provided with a clasping point, and an axial line is provided at the center of the elastic arm; and
a base provided with a groove, and provided with a first locating bar on its top and with a second locating bar on its bottom corresponding to the first locating bar such that the clasping portion can be accommodated in the groove;
consequently, the clasping portion can swing about the axial line after the clasping structure is being assembled.

2. The clasping structure as defined in claim 1, wherein the holding portion is of a fish-spear shape.

3. The clasping structure as defined in claim 1, wherein the fixed portion is further provided with a protruding tip.

4. The clasping structure as defined in claim 1, wherein the groove penetrates through the upper and lower surface of the base and the first and second locating bars.

5. The clasping structure as defined in claim 1, wherein part of the clasping portion protrudes out of the first locating bar and the holding portion also partially protrudes out of the second locating bar.

6. The clasping structure as defined in claim 1, wherein the axial line is located in the inner side of the clasping point when in the clasping direction.

7. A clasping structure comprising:
a clasping part provided with a clasping portion, whose inner bottom is provided with a clasping point and also provided with a pivoting portion corresponding to the clasping portion;
a coordinating part having a main body and an elastic arm which is formed by extending one side of the main body upward and then backward with a certain portion springing upward; and
a base provided with a groove and disposed with a first locating bar on its top and with a second locating bar on its bottom corresponding to the first locating bar such that the clasping portion can be accommodated in the groove;
consequently, when the clasping part and the coordinating part are assembled into the base, the end of the pivoting portion and its corresponding wall in the coordinating part can limit the swinging angle of the clasp.

8. The clasping structure as defined in claim 7, wherein the elastic arm presses against the pivoting portion of the clasp.

9. The clasping structure as defined in claim 7, wherein the coordinating part is further provided with an indent, which corresponds to the pivoting portion of the clasp.

10. The clasping structure as defined in claim 7, wherein the pivoting portion is provided with protruding point to accommodate and to swing relative to the indent.

11. The clasping structure as defined in claim 7, wherein the clasping portion and the pivoting portion are further provided with a connecting portion therebetween.

12. The clasping structure as defined in claim 11, wherein the connecting portion is formed by extending the main body upward and then backward.

13. The clasping structure as defined in claim 7, wherein the groove penetrates through the upper and lower surface of the base and the first and second locating bars.

14. The clasping structure as defined in claim 7, wherein part of the clasping portion protrudes out of the first locating bar and the holding portion also partially protrudes out of the second locating bar.

15. The clasping structure as defined in claim 7, wherein the center of the protruding point is provided with a swinging axial line, which is located in the inner side of the clasping point when in the clasping direction.
